(19) United States
(12) Patent Application Publication
(10) Pub. No.: US 2014/0077210 A1
(43) Pub. Date: Mar. 20, 2014

(54) AMORPHOUS SILICON PHOTODETECTOR WITH LOW DARK CURRENT

(71) Applicant: INTERNATIONAL BUSINESS MACHINES CORPORATION, Armonk, NY (US)

(72) Inventors: Bahman Hekmatshoartabari, White Plains, NY (US); Devendra K. Sadana, Pleasantville, NY (US); Ghavam G. Shahidi, Round Ridge, NY (US); Davood Shahrjerdi, White Plains, NY (US)

(73) Assignee: INTERNATIONAL BUSINESS MACHINES CORPORATION, Armonk, NY (US)

(21) Appl. No.: 13/623,866

(22) Filed: Sep. 20, 2012

(51) Int. Cl. H01L 31/105; H01L 31/0368; H01L 31/0376

(52) U.S. Cl. 257/53; 257/49; 257/E31.043; 257/E31.047; 257/E31.061

(57) ABSTRACT

A p-i-n photodetector includes at least one multilayer contact structure including wide gap and narrow gap layers to reduce dark current. The multilayer contact structure includes one or more wide band gap semiconductor layers in alternating sequence with one or more narrow band gap contact layers. A fabrication method of the photodetector includes transfer-doping of the narrow band gap contact layers, which are deposited in alternating sequence with wide band gap semiconductor layers.

### FIELD

The present disclosure relates to the physical sciences and, more particularly, to photodetectors, including those based on hydrogenated amorphous silicon.

### BACKGROUND

The sensitivity of p-i-n photodetectors based on hydrogenated amorphous silicon (a-Si:H) is limited by the dark current of the p-i-n junction. A significant portion of the dark current is due to the low doping efficiency of boron in p-type a-Si:H.

Referring to FIG. 1, a conventional photoreceptor 10 includes an intrinsic hydrogenated amorphous silicon photoreceptive layer 12, a p-layer 14 adjoining one surface of the photoreceptive layer, and an n-layer 16 adjoining the opposite surface thereof. The n-layer and p-layer are doped semiconductor layers (hereafter referred to as contact layers) used for establishing a built-in electric field across the intrinsic layer. A simplified schematic energy band diagram of the conventional structure is shown in FIG. 2.

Amorphous superlattice structures formed between metal contacts have been developed using alternating layers of a-SiNx:H and a-Si:H as well as alternating layers of a-Si:H and a-SiGe:H. Such structures having layers running perpendicular to the metal contacts have shown enhanced a-Si:H conductivity due to transfer doping of, for example, a-Si:H by a-SiNx:H. In structures wherein the layers of the superlattice are parallel to the metal contact layers, higher tunneling current is facilitated by defect states at room temperature.

### BRIEF SUMMARY

In accordance with the principles discussed herein, a p-i-n photodetector structure is provided that has a low dark discharge current. The photodetector structure includes a photosensitive intrinsic amorphous, nanocrystalline or microcrystalline semiconductor layer having top and bottom surfaces. A first electrically conductive contact structure having a first doping type adjoins the top surface of the intrinsic semiconductor layer, the first contact structure including first and second wide band gap semiconductor layers and a transfer doped narrow band gap contact layer between and adjoining the first and second wide band gap semiconductor layers. A second electrically conductive contact structure adjoins the bottom surface of the intrinsic semiconductor layer. The second contact structure comprises a semiconductor material having a second doping type opposite to the first doping type. The first and second contact structures establish a built-in electric field across the intrinsic semiconductor layer.

In accordance with a further embodiment, a p-i-n photoconductor structure includes a photosensitive intrinsic amorphous, nanocrystalline or microcrystalline semiconductor layer having top and bottom surfaces. An electrically conductive p-type first contact structure adjoins the top surface of the intrinsic amorphous semiconductor layer, the first contract structure comprising one or more wide band gap semiconductor layers and one or more narrow band gap semiconductor layers. The one or more narrow band gap semiconductor layers have band gaps smaller than those of the wide band gap semiconductor layers. The one or more narrow band gap semiconductor layers and the one or more wide band gap semiconductor layers are arranged in alternating sequence, each of the one or more narrow band gap semiconductor layers adjoining at least one wide band gap semiconductor layer and being transfer doped by at least one of the one or more wide band gap semiconductor layers. An electrically conductive second contact structure comprised of n-type semiconductor material adjoins the bottom surface of the intrinsic semiconductor layer. The first and second contact structures establish a built-in electric field across the intrinsic semiconductor layer.

A p-i-n photodetector structure in accordance with a further embodiment includes a photosensitive intrinsic amorphous, nanocrystalline or microcrystalline semiconductor layer having top and bottom surfaces. An electrically conductive n-type first contact structure adjoins the top surface of the intrinsic semiconductor layer, the first contract structure comprising one or more wide band gap semiconductor layers and one or more narrow band gap semiconductor layers. The one or more narrow band gap semiconductor layers have band gaps smaller than those of the wide band gap semiconductor layers. The one or more narrow band gap semiconductor layers and the one or more wide band gap semiconductor layers are arranged in alternating sequence, each of the one or more narrow band gap semiconductor layers adjoining at least one wide band gap semiconductor layer and being transfer doped by at least one of the one or more wide band gap semiconductor layers. An electrically conductive second contact structure comprised of p-type semiconductor material adjoins the bottom surface of the intrinsic semiconductor layer, the first and second contact structures establishing a built-in electric field across the intrinsic semiconductor layer.

In accordance with further principles discussed herein, a fabrication method is disclosed for fabricating p-i-n photodetector structures exhibiting reduced dark current at their p-i-n junctions. The method includes forming a first, electrically conductive, multi-layer p-type contact structure including one or more wide band gap semiconductor layers and one or more narrow band gap semiconductor layers in alternating sequence such that the one or more narrow band gap semiconductor layers are transfer doped by at least one of the one or more wide band gap semiconductor layers. The method further includes forming a photosensitive hydrogenated amorphous, nanocrystalline or microcrystalline intrinsic semiconductor layer and forming a second, electrically conductive n-type contact structure, the first and second contact structures and the intrinsic semiconductor layer being formed in alternating sequence such that the first contact structure adjoins a first surface of the intrinsic semiconductor layer and the second contact structure adjoins a second surface of the intrinsic semiconductor layer, forming a p-i-n photodetector structure. The first and second contact structures establish a built-in electric field across the intrinsic semiconductor layer.

A further exemplary method includes forming a first, electrically conductive, multi-layer n-type contact structure including one or more wide band gap semiconductor layers and one or more narrow band gap semiconductor layers in alternating sequence such that the one or more narrow band gap semiconductor layers are transfer doped by at least one of the one or more wide band gap semiconductor layers. The method further includes forming a photosensitive hydrogenated amorphous, nanocrystalline or microcrystalline intrinsic semiconductor layer and forming a second, electrically conductive p-type contact structure. The first and second contact structures and the intrinsic semiconductor layer are formed in alternating sequence such that the first contact structure adjoins a first surface of the intrinsic semiconductor layer and the second contact structure adjoins a second surface of the intrinsic semiconductor layer, forming a p-i-n photodetector structure. The first and second contact structures establish a built-in electric field across the intrinsic semiconductor layer.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

Substantial beneficial technical effects are provided by the exemplary structures and methods disclosed herein. For example, one or more embodiments may provide one or more of the following advantages:

Low dark current;

Improved light current to dark current ratio;

Contacts having effectively larger band-offset and effectively higher doping.

These and other features and advantages of the present disclosure will become apparent from the following detailed description of illustrative embodiments thereof, which is to be read in connection with the accompanying drawings.

### BRIEF DESCRIPTION OF THE DRAWINGS

FIG. 1 shows a schematic illustration of a prior art a-Si:H photodetector;

FIG. 2 shows a simplified schematic illustration of an energy band diagram of the conventional photodetector as exemplified by FIG. 1;

FIG. 3 is a schematic illustration of a p-i-n photodetector as disclosed herein;

FIG. 4 shows a simplified schematic illustration of an energy band diagram of a photodetector as exemplified by FIG. 3;

FIG. 5 shows a schematic, cross-sectional view of a p-type contact layer in accordance with one or more exemplary embodiments;

FIGS. 6A and 6B show schematic, simplified energy band diagrams of a conventional p-i-n photodiode structure and a p-i-n photodiode structure in accordance with an exemplary embodiment, respectively;

FIGS. 7A and 7B show schematic, cross-sectional views of a conventional p-i-n photodiode structure and a p-i-n photodiode structure in accordance with an exemplary embodiment, respectively, and

FIG. 8 shows experimental dark and light I-V characteristics of test structures corresponding to the structures shown in FIGS. 7A and 7B, respectively.

### DETAILED DESCRIPTION

The sensitivity of p-i-n photodetectors such as p-i-n photodiodes based on hydrogenated amorphous silicon (a-Si:H) is limited by the dark current of the p-i-n junction in such photodetectors. A significant portion of the dark current is due to the low doping efficiency of boron in p-type a-Si:H. Improved a-Si:H p-i-n photodetector structures are disclosed herein, each preferably comprised of a transfer doped narrow gap semiconductor layer included in the p-type contact.

The doping efficiency of boron in p⁺ a-Si:H is low because of the large valence band tail density of states in a-Si:H which leads to the dopant-induced defect creation phenomenon also known as defect-dopant coupling. To reduce the dark current of the p-i-n junction, one needs to increase the valence band offset between the p contact and the intrinsic semiconductor layer and/or improve the activated doping level in the p contact. The valence band offset may be increased by incorporating C, O or N in the p⁺ a-Si:H layer. However, the doping efficiency of p⁺ a-Si:H is reduced by incorporation of these elements. Improving the doping efficiency of boron is fundamentally challenging and practically the Fermi level in p+ a-Si:H is pinned at about 0.3-0.4 eV above the valence band offset due to the presence of large defects created as a result of doping incorporation. Photodetector structures having multilayer p-type contacts are provided to address one or more of these issues, as discussed below with respect to exemplary embodiments.

Referring to FIG. 3, an amorphous silicon photodetector structure 20 includes an intrinsic semiconductor layer (“i-layer”) 22 and multilayer contacts 24, 26. The p-type contact 24 is comprised of a plurality of p-layers. A narrow-gap layer 24A is positioned between wide-gap layers 24B. In this exemplary embodiment, the n-type contact 26 is comprised of a plurality of n-layers 26A, 26B, one of which 26A has a relatively narrow band gap and is transfer doped.

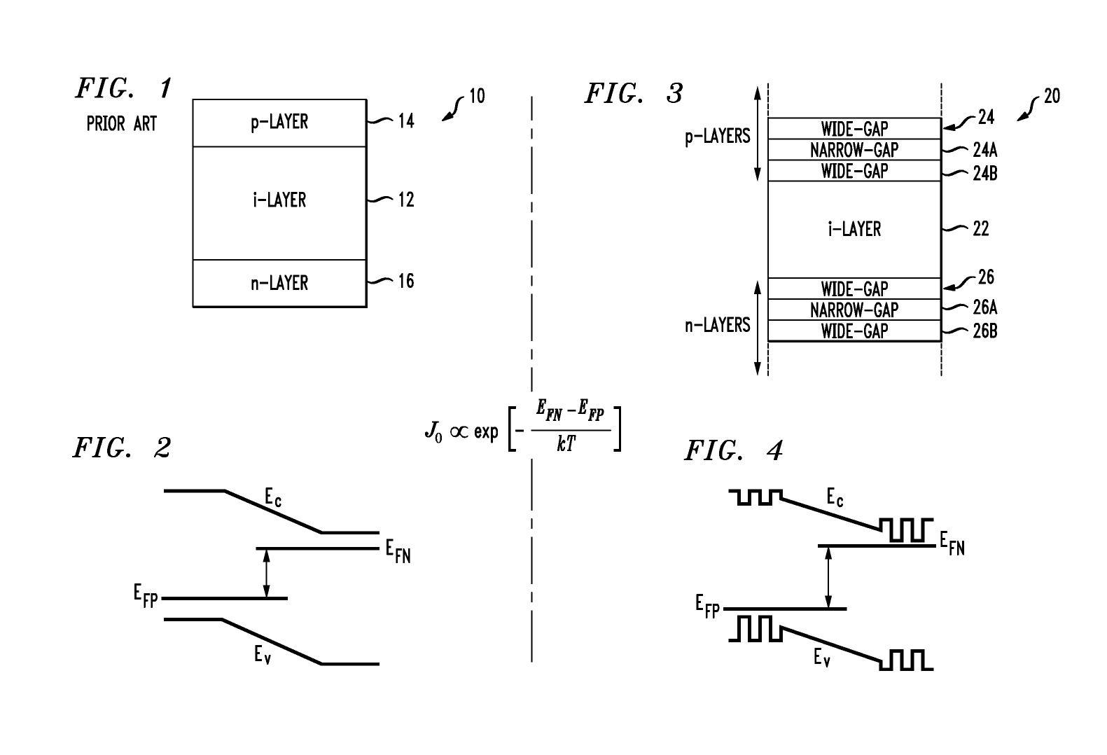

The intrinsic semiconductor layer may or may not contain C, Ge, N, O, Cl, F, D or combinations thereof. In some embodiments, the intrinsic layer 22 may contain a nanocrystalline or microcrystalline portion. The intrinsic layer 22 as described herein comprises a photosensitive hydrogenated amorphous, nanocrystalline or microcrystalline intrinsic semiconductor layer, it being understood that such layer may be partially or entirely amorphous or partially or entirely microcrystalline or nanocrystalline. In some embodiments, the a-Si:H intrinsic layer 22 (also known by those of skill in the art as a photoreceptive layer, or transport layer) may be doped slightly p-type to compensate for the slight intrinsic n-type conductivity of undoped a-Si:H by counterdoping and therefore reduce the dark conductivity of the a-Si:H intrinsic semiconductor layer 22. A simplified schematic energy band diagram of the exemplary structure 20 is provided in FIG. 4. Comparing the diagram provided in FIG. 2 with that in FIG. 4, the multi-layer contacts 24, 26 provide larger band-offset than conventional structures. The larger band-offset and effectively higher activated doping lead to a reduction in dark current.

The band gaps of both the wide-gap and narrow-gap layers comprising the contact 24 can be tuned by composition, crystalline fraction, growth conditions, and combinations thereof. The narrow-gap layer(s) 24A is doped by transfer-doping (also known as modulation doping), i.e. hole transfer from the wide gap semiconductor layers 24B into the narrow-gap material, forming one or more p+ doped layers. Doping efficiency of amorphous materials is generally low because of the large density of defects in these materials, and also because the introduction of impurity atoms (dopants) creates extra defects. (This phenomenon is known as defect-dopant coupling, or dopant-induced defect creation). Doping efficiency of a-Ge:H or a-SiGe:H is generally lower than that of a-Si:H; however, a narrow band gap layer comprising a-Ge:H or a-SiGe:H may be efficiently doped by transfer of holes from a-SiC:H, a-SiO:H, a-SiN:H (or combinations thereof) without the need to introduce extra dopants in a-Ge:H or a-SiGe:H. The total thickness of the wide-gap layers 24B is preferably below 50 nm, although larger thicknesses are also possible. The thickness of each of the wide band gap layers 24B is preferably is preferably in the range of 5 to 25 nm, although thicker or thinner layers can be used as well. The total thickness of the narrow band gap layers 24A is preferably below 75 nm, although larger thicknesses are also possible. The thickness of each of the narrow-gap layers is preferably in the range of 3 to 30 nm, although thinner or thicker layers can be used as well. As shown in FIG. 3, one of the wide band gap semiconductor layers 24B of the contact 24 adjoins the intrinsic semiconductor (receptor) layer 22.

A wide-gap layer 24B present in the contact 24 has a band gap larger than that of a narrow-gap layer 24A by at least 0.1 eV and preferably by at least 0.2 eV. The terms “wide” and “narrow” as applied to the band gaps of the wide band gap layers and narrow band gap layers described herein are accordingly relative terms. However, a wide-gap semiconductor layer may have a band gap larger, equal or smaller than that of the intrinsic semiconductor layer 22. The band gap of a-Si:H is typically in the range of 1.7-1.8 eV; however, as known in the art, larger or smaller band gaps are possible by varying the deposition conditions. The band gap of a-Ge:H is typically in the range of 0.9-1.2 eV; however, similar to a-Si:H, larger and smaller band gaps are also possible. An alloy of two semiconductor materials has a band gap depending linearly on the atomic fractions of the two semiconductors, e.g. an alloy of a-SiₓGe₁₋ₓ has a band gap of xE_{g1}+(1−x)E_{g2}, where E_{g1} is the band gap of a-Si:H, E_{g2} is the band gap of a-Ge:H, x the atomic fraction of Si (number of Si atoms in the lattice divided by the total number of Si and Ge atoms), and ₁₋ₓ the atomic fraction of Ge. (note that 0≦×≦1). Similarly, the band gap of an a-SiₓC₁₋ₓ:H alloy is increased typically from 1.7-1.8 eV to 3.6-3.7 eV as the atomic fraction of C is increased from 0 to 1. Addition of N, O or both to a-Si:H, a-Ge:H or a-SiGe:H increases the band gap, but the increase in band gap is not typically a linear function of the atomic percentage. Hydrogenated amorphous silicon-nitride (a-SiₓN₁₋ₓ:H) typically has a band gap of 5-5.5 eV for the stoichiometric composition x=0.42, and the band gap can be varied by changing the atomic percentage of N. Hydrogenated amorphous silicon oxide (a-SiO:H) has band gaps comparable with a-SiN:H. The band gap of semiconductor alloys or oxides/nitrides may be varied by changing the crystalline portion of the materials. The band gap of nanocrystalline or microcrystalline materials is generally lower than that of amorphous materials having the same composition. The band gap of hydrogenated nano/microcrystalline Si varies between ˜1.1 eV to ˜1.8 eV as the material structure varies from fully single/poly-crystalline to fully amorphous. Similarly, the band gap of hydrogenated nano/microcrystalline Ge varies between ˜0.6 eV to ˜1.2 eV as the material structure varies from fully single/poly-crystalline to fully amorphous. The band gaps of hydrogenated nano/micro-crystalline SiC, SiO, SiGeO, GeO and SiN compounds are lower than that of a-SiC:H, a-SiO:H, a-SiGeO:H, a-GeO:H and a-SiN:H, respectively. (This also applies to combinations thereof). In the PECVD process, the crystalline portion of the materials may be increased by increasing the hydrogen dilution of the source gases, increasing the plasma frequency (typically up to 120 MHz) or both. For example, hydrogenated nano-crystalline silicon oxide (nc-SiO:H) may be grown by PECVD with band gap in the range of 0.8-2.5 eV, depending on the growth conditions and oxygen content of the film.

Referring again to the structure 20 of FIG. 3, in one exemplary embodiment the i-layer 22 is an a-Si:H layer. In this exemplary embodiment, the p-side wide-gap layers 24B may be a-SiC:H, μc-SiC:H, a-SiO:H, μc-SiO:H, a-SiN:H, μc-SiN:H, or a-C:H. The p-side narrow-gap layers 24A may be a-Si:H, μc-Si:H, a-SiGe:H, μ-SiGe:H, μ-SiGeO:H, or μc-SiC:H. Materials that may be used to form the n-side narrow-gap layers 26A include a-Si:H, μc-Si:H, μc-SiC:H. The n-side wide-gap layers 26B may be a-SiC:H, μc-SiC:H, a-SiO:H, or μc-SiO:H. It should be appreciated that the lists of possible materials for the layers comprising each contact are exemplary as opposed to limiting.

In a further exemplary embodiment of the structure 20 of FIG. 3, the i-layer 22 is a-SiGe:H. Exemplary materials for the other layers of the p-i-n structure may include: p-side wide-gap layers 24B: a-Si:H, a-SiC:H, μc-SiC:H, a-SiGeC:H, a-SiO:H, μc-SiO:H, a-SiN:H, μc-SiN:H; p-side narrow-gap layers 24A: a-Ge:H, μc-SiGe:H, a-SiGe:H, μ-SiGe:H, μ-SiGeO:H; n-side narrow-gap layers 26A: μc-Si:H, μc-SiGe:H, a-SiGe:H n-side wide-gap layers 26B: a-Si:H, μc-SiC:H, a-SiO:H, μc-SiO:H. In other embodiments, the i-layer 22 may comprise a-Ge:H. An exemplary i-layer may be described as comprising a-SiₓGe₁₋ₓ:H where 0≦×≦1. As discussed above, it is understood that the hydrogenated “amorphous, nanocrystalline or microcrystalline” i-layer 22 as described herein may be entirely or only partially amorphous or entirely or only partially nanocrystalline or microcrystalline. An “amorphous” i-layer, for example, may or may not include nanocrystalline and/or microcrystalline portions. A “microcrystalline” i-layer likewise may or may not include amorphous and/or nanocrystalline portions.

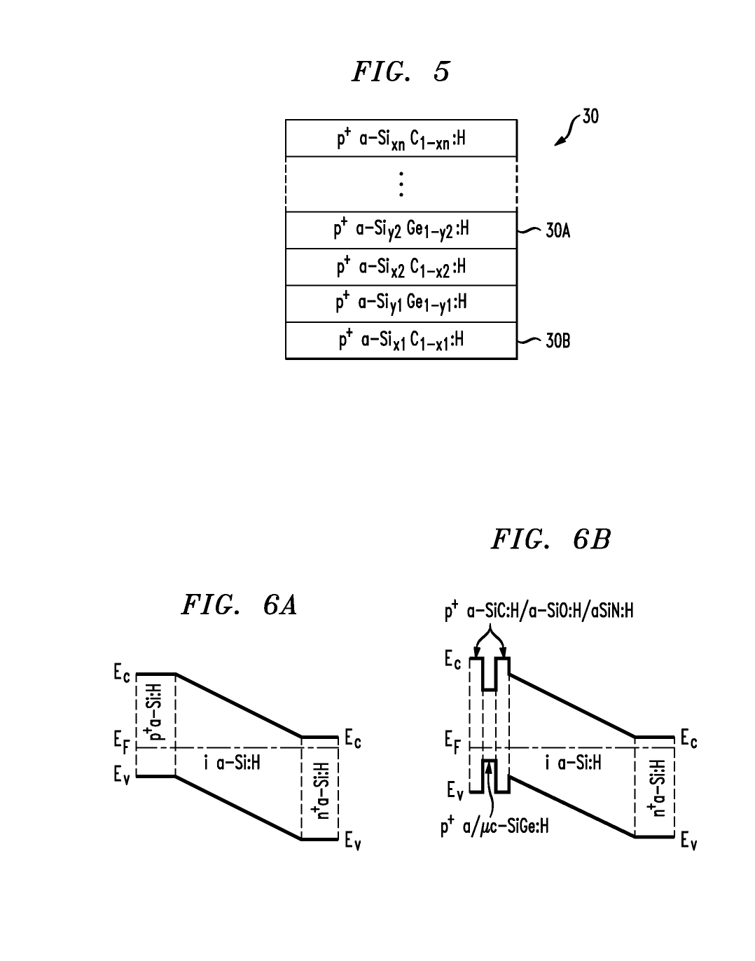

An exemplary multilayer p-type contact 30 for a p-i-n photodiode is shown in FIG. 5. Schematic energy band diagrams of conventional and exemplary p-i-n structures having conventional and exemplary contacts described below is provided in FIGS. 6A and 6B, respectively. The narrow-gap material comprising the narrow-gap layers 30A is doped by transfer-doping (modulation) doping, i.e. hole transfer from the wide gap material. Each narrow gap layer preferably, though not necessarily, adjoins two wide gap semiconductor layers. Doping efficiency of amorphous materials such including a-Si:H is generally low because of the large density of defects in these materials, and also because introduction of impurity atoms (dopants) creates extra defects. (This is known as defect-dopant coupling, or dopant-induced defect creation.) Doping efficiency of a-SiGe:H is lower than that of a-Si:H. However, as also discussed above, a-SiGe:H may be efficiency doped by transfer of holes from materials such as a-SiC:H, a-SiO:H or a-SiN:H without the need to introduce extra dopants in a-SiGe:H. As a result, the effective doping efficiency of the p-type contact layer 30 is improved, resulting in a stronger built-in electric field across the intrinsic layer. Hole transport during illumination is not compromised if the wide gap layers are sufficiently thin. (It should be noted than sufficiently thin wide gap layers are feasible without compromising the built-in electric field due to the presence of highly doped narrow gap layer.) In addition, the formation of mini-bands in the a-SiGe:H quantum well (in the valance band) due to quantum confinement as known in the art further facilitates hole transport.

The exemplary p-type contact layer 30 shown in FIG. 5 is comprised of a supperlattice multilayer, where n≧2 (n being the number of wide band gap layers). The wide gap material may be a-SiC:H, a-SiO:H, a-SiN:H, or a combination thereof (only a-SiC:H shown in the drawing), and may contain a crystalline fraction. The narrow gap layers may be amorphous, nano, micro, or polycrystalline. Any or all of the narrow gap layers 30A may be undoped or lightly doped, while at least one of the wide gap layers 30B is doped (0≦xᵢ,yᵢ 1; xᵢ and yᵢ may be constant or vary across each layer; for all 1≦i≦n). The index xᵢ refers to the atomic percentage of Si in the a-SiC:H alloy (i.e. ratio of the number of Si atoms to the total number of Si and C atoms in the a-SiC:H lattice), forming the ith wide-gap layer. The atomic percentage of Si may be constant across the ith wide-gap layer or vary across the ith wide-gap layer, for example by varying the gas flow ratio of the Si-containing gas source to C-containing gas source during the growth of the ith wide-gap layer. The index yᵢ refers to the atomic percentage of Si in the a-SiGe:H alloy (i.e. ratio of the number of Si atoms to the total number of Si and Ge atoms in the a-SiGe:H lattice), forming the ith narrow-gap layer. The atomic percentage of Si may be constant across the ith narrow-gap layer or vary across the ith narrow-gap layer, for example by varying the gas flow ratio of the Si-containing gas source to Ge-containing gas source during the growth of the ith narrow-gap layer. All layers may contain fluorine (F), deuterium (D), chlorine (Cl) or combinations thereof. The narrow band gap layers may intentionally or unintentionally contain C. Similarly, the wide band gap layers 30B may intentionally or unintentionally contain Ge. As the narrow band gap layers 30A in this illustrative embodiment are p+ a-SiGe:H, they are effective in enhancing the electric field across the intrinsic semiconductor layer 22 (shown in FIG. 3) of the photodetector 20. FIGS. 6A and 6B show simplified energy band diagrams of a conventional p-i-n photodiode structure and a photodiode structure having a contact structure as exemplified in FIG. 5 wherein n=2 (comprised of three layers, i.e. n=2, and employing two wide band gap layers 30B). The wide gap and narrow gap materials identified in FIG. 6B are exemplary and, as in the structure illustrated in FIG. 5, may be employed in combination.

As discussed above, p+ layers such as employed in the exemplary contact structure of FIG. 5 enhance the built-in electric field across the i-layer 22 as compared to the conventional structure shown in FIG. 1. This disclosure further encompasses photodetectors that employ n+ contact layers that enhance the built-in electric field across the i-layer 22, including photodetectors that may or may not have multi-layer p-type contacts. Referring to FIG. 3, the contact structure 26 includes n+ wide band gap layers 26B and n+ narrow band gap contact layers 26A. Modulation (transfer) doping of the narrow band gap contact layer(s) 26A occurs as electrons are transferred thereto from the wide band gap layers 26B. Transfer doping provides greater benefits with respect to p+ type contact layers as p-type doping by dopant atoms is typically less efficient than n-type doping by dopant atoms in amorphous/nanocrystalline materials such as a-Si:H.

The contact structures 24, 26, 30 and i-layer 22 may be formed by any physical or chemical growth or deposition method known to those of skill in the art. The preferred method is plasma enhanced chemical vapor deposition (PECVD) although other techniques such as hot-wire CVD, sputtering or electro-deposition may be used for forming some or all of the layers. In case of PECVD, the gas source used for Si containing layers is typically silane (SiH₄) although other gases such as disilane (Si₂H₆), dichlorosilane (DCS), tetrafluorosilane (SiF₄) or combinations thereof may be used as well. The gas source used for Ge containing layers is typically germane (GeH₄). The gas source used for C containing layers is typically methane (CH₄), ethylene (C₂H₄), propylene (C₃H₆) but other sources (typically of the form CₓH_{y}) may be used as well. In-situ p-type doping is typically performed using diborane (B₂H₆) or trimethylboron (TMB) sources and in-situ n-type doping is typically performed using phosphine (PH₃) gas source, although other dopant sources may be used as well. Ammonia (NH₃), nitrous oxide (N₂O) or other gas sources may be used for nitrogen containing layers. Carbon dioxide (CO₂), N₂O or O₂ may be used to provide oxygen for oxygen containing layers. A carrier gas such as hydrogen (H₂), deuterium (D₂) helium (He) or argon (Ar) may be used for any or all of the layers. The carrier gas may be pre-mixed with the gas sources or flowed simultaneously with the gas source at the time of growth.

The wide band gap semiconductor materials of the p-type contact 30 are formed in sufficiently small thicknesses, in the range of 5-25 nm for each layer and less than 50 nm in total thickness, to minimize electron injection from these layers and to prevent or reduce compromising carrier transport during illumination of the photodetector. The narrow band gap contact layers are formed in alternating sequence with the formation of the wide band gap semiconductor layers, resulting in both the top and bottom surfaces of each narrow band gap contact layer 24A adjoining a wide band gap semiconductor layer 24B in the preferred embodiments. In some exemplary embodiments, however, only the top surface of the narrow gap layer would adjoin a wide gap layer. In other exemplary embodiments, only the bottom surface of this narrow gap layer would adjoin a wide gap layer. In the preferred embodiments, higher transfer doping is possible as holes are transferred from two adjoining wide gap layers instead of only one. The highly doped p+ a-SiGe:H narrow band gap layer(s), such as shown in the exemplary embodiment of FIG. 5, may be formed as thin layers, each in the range of 3-30 nm, with a combined thickness preferably below 75 nm.

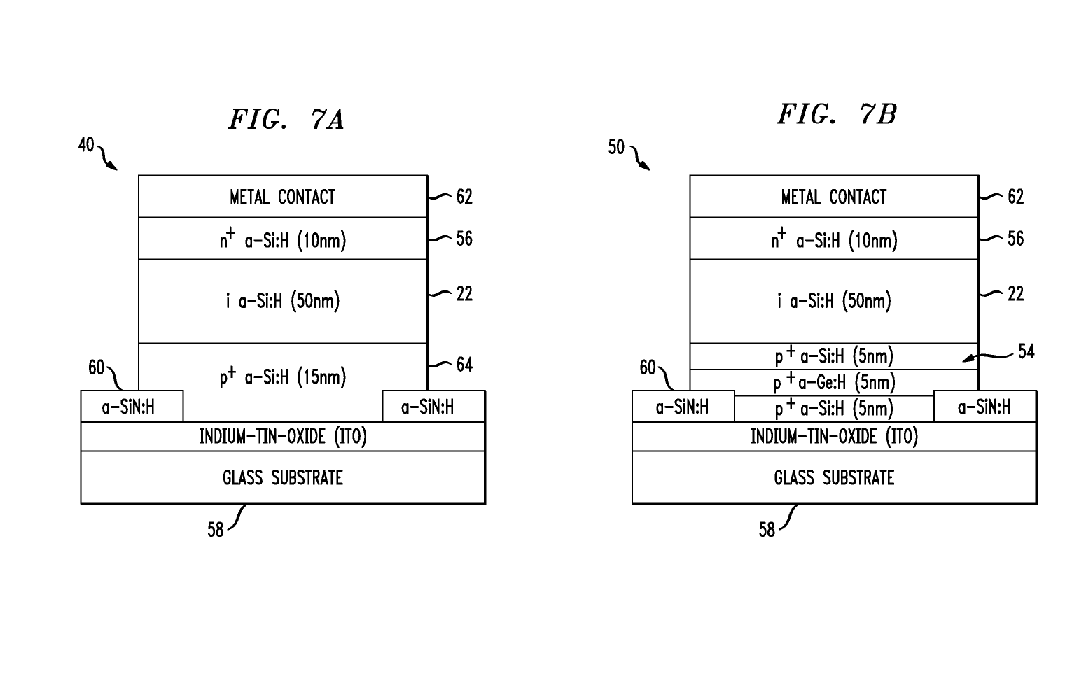

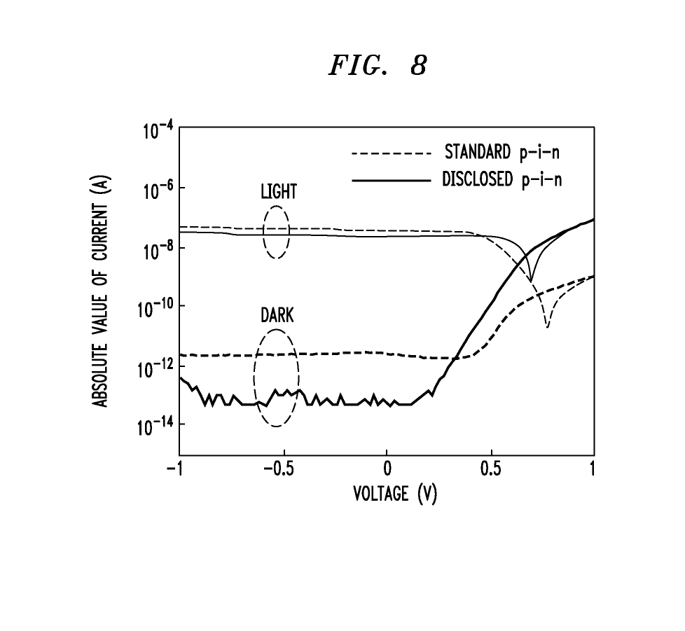

Exemplary test structures as illustrated in FIG. 7A (conventional p-i-n photodiode 40) and FIG. 7B (p-i-n photodiode 50 according to one exemplary embodiment) demonstrate the efficacy of the structures disclosed herein. Hydrogenated amorphous silicon-nitride 60 (a-SiN:H) was grown by plasma-enhanced chemical vapor deposition (PECVD) on commercially available ITO-coated glass substrates 58, and patterned using standard photolithography for device isolation as well as edge passivation of the devices. Next the conventional p⁺/i/n⁺ a-Si:H stack of FIG. 7A and the exemplary p⁺ a-Si:H/p⁺ a-Ge:H/p⁺ a-Si:H/i a-Si:H/n⁺ a-Si:H stack shown in FIG. 7B were grown using PECVD. The stack of the exemplary structure 50 accordingly comprised an intrinsic semiconductor layer 22 having a thickness of fifty nanometers and adjoining a multi-layer p-layer 54 on one surface and a ten nanometer thick single-layer n-layer 56 on its opposite surface, each of the individual p-layers comprising the p-layer 54 having a thickness of five nanometers. The stack of the conventional structure included a fifteen nanometer thick p-layer contact 64 which was not formed as a superlattice multi-layer structure. The metal contacts 62 were then formed using a lift-off process, (thermal evaporation of metal onto patterned photoresist, followed by stripping of the photoresist). Next, the metal contacts were used as a hard mask for patterning/isolation of the p-i-n devices 40, 50 using reactive-ion-etching. It will be appreciated by those skilled in the art, that other known techniques could be alternatively used for the formation of the metal grid 62 and/or for patterning/isolation of the p-i-n devices 40, 50, without altering the structure or function of the p-i-n devices 40, 50. For example, the metal grid could be formed by screen printing or electro-plating using patterned photoresist as a mask. The experimental dark and light I-V characteristics of the test devices are plotted in FIG. 8. The dark current of the exemplary p-i-n photodiodes 50 is lower than that of the conventional p-i-n photodiodes 40 by a factor of larger than ten (10). The photo-response (light I-V) of the conventional and exemplary photodiodes are very close to each other. This shows that the sensitivity of the exemplary p-i-n photodiodes, i.e. the ratio of the light current to dark current, is better than that of the conventional photodiodes by a factor of larger than ten.

Given the discussion thus far, a p-i-n photodetector structure is disclosed herein wherein at least one of the doped contact structures is comprised of wide gap and narrow gap layers, and further wherein the desired large band-offset is provided by the wide-gap material and the desired high doping activation is provided by transfer doping of the narrow gap material. A photodetector structure in accordance with a first exemplary embodiment includes a photosensitive intrinsic amorphous, nanocrystalline or microcrystalline semiconductor layer having top and bottom surfaces. A first electrically conductive contact structure having a first doping type adjoins the top surface of the intrinsic semiconductor layer. The first contact structure includes first and second wide band gap semiconductor layers and a transfer doped narrow band gap contact layer between and adjoining the first and second wide band gap semiconductor layers. A second electrically conductive contact structure adjoins the bottom surface of the intrinsic semiconductor layer, the second contact structure comprising a semiconductor material having a second doping type opposite to the first doping type, the first and second contact structures establishing a built-in electric field across the intrinsic semiconductor layer. FIG. 3 shows an exemplary structure 20. A metal contact layer on the second contact structure is further included in one or more embodiments, such as the embodiment of FIG. 7B. The first contact structure is p-type and the second contact structure is n-type in one or more exemplary embodiments of the photodetector structure. The intrinsic semiconductor layer comprises a-SiₓGe₁₋ₓ:H where 0≦x≦1 in one or more embodiments thereof. In some embodiments, the second electrically conductive contact structure is an n-type layer comprising first and second wide band gap n-type semiconductor layers and a transfer doped narrow band gap semiconductor layer between and adjoining the first and second wide band gap n-type semiconductor layers. The wide band gap and narrow band gap layers are within certain thickness ranges and/or are comprised of specific materials as described above in one or more exemplary embodiments.

A p-i-n photodetector structure in accordance with a further exemplary embodiment includes a photosensitive intrinsic amorphous, nanocrystalline or microcrystalline semiconductor layer having top and bottom surfaces. An electrically conductive p-type first contact structure adjoins the top surface of the intrinsic semiconductor layer, the first contract structure comprising one or more wide band gap semiconductor layers and one or more narrow band gap semiconductor layers. FIG. 7B discloses such a structure wherein the p-type first contact structure 54 includes such layers and adjoins a top surface of the i-layer 22. The one or more narrow band gap semiconductor layers have band gaps smaller than those of the wide band gap semiconductor layers. The one or more narrow band gap semiconductor layers and the one or more wide band gap semiconductor layers are arranged in alternating sequence, each of the one or more narrow band gap semiconductor layers adjoining at least one wide band gap semiconductor layer and being transfer doped by at least one of the one or more wide band gap semiconductor layers. An electrically conductive second contact structure comprised of n-type semiconductor material adjoins the bottom surface of the intrinsic semiconductor layer, the first and second contact structures establishing a built-in electric field across the intrinsic semiconductor layer. The exemplary structure 50 shown in FIG. 7B includes a second contact structure 56 that contacts the bottom surface of the i-layer 22. (The terms “top” and “bottom” designate relative positions, as exemplified in FIG. 7B.) The intrinsic semiconductor layer is comprised of a-SiₓGe₁₋ₓ:H where 0≦x≦1 in one or more exemplary embodiments. In one or more further embodiments, the first contact structure includes more than one wide band gap semiconductor layer such that at least one of the one or more narrow band gap semiconductor layers adjoins two wide band gap semiconductor layers. Such a structure is also shown in FIG. 7B, where the p+ a-Ge:H narrow gap contact layer is positioned between wide gap p+ a-Si:H wide band gap layers. In the exemplary structure 50, one of the wide band gap semiconductor layers of the p-type contact structure 54 contacts the i-layer while the second wide band gap layer contacts the ITO layer of the substrate 58. As discussed above, transfer doping is enhanced when the first contact structure is formed in such a manner.

A p-i-n photodetector structure in accordance with a further exemplary embodiment includes a photosensitive intrinsic amorphous, nanocrystalline or microcrystalline semiconductor layer having top and bottom surfaces. In this further embodiment, an electrically conductive n-type first contact structure adjoins the top surface of the intrinsic semiconductor layer. The first contract structure comprises one or more wide band gap semiconductor layers and one or more narrow band gap semiconductor layers, the one or more narrow band gap semiconductor layers having band gaps smaller than those of the wide band gap semiconductor layers. The one or more narrow band gap semiconductor layers and the one or more wide band gap semiconductor layers are arranged in alternating sequence, each of the one or more narrow band gap semiconductor layers adjoining at least one wide band gap semiconductor layer and being transfer doped by at least one of the one or more wide band gap semiconductor layers. An electrically conductive second contact structure comprised of p-type semiconductor material adjoins the bottom surface of the intrinsic semiconductor layer, the first and second contact structures establishing a built-in electric field across the intrinsic semiconductor layer. The intrinsic semiconductor layer comprises a-SiₓGe₁₋ₓ:H where 0≦x≦1 in one or more embodiments. The one or more narrow band gap semiconductor layers in this or other exemplary embodiments as described in the preceding two paragraphs may have a thickness between 3-30 nm. The one or more wide band gap semiconductor layers may have a thickness between 5-25 nm. The photodetector structure further includes more than one wide band gap semiconductor layer in a further exemplary embodiment, wherein at least one of the one or more narrow band gap semiconductor layers adjoins two wide band gap semiconductor layers. The total thickness of the wide band gap semiconductor layers is less than 50 nm in one or more embodiments of the photodetector structure.

A method of forming a p-i-n photodetector in accordance with one exemplary embodiment includes forming a first, electrically conductive, multi-layer p-type contact structure including one or more wide band gap semiconductor layers and one or more narrow band gap semiconductor layers in alternating sequence such that the one or more narrow band gap semiconductor layers are transfer doped by at least one of the one or more wide band gap semiconductor layers, forming a photosensitive hydrogenated amorphous, nanocrystalline or micro-crystalline intrinsic semiconductor layer, and forming a second, electrically conductive n-type contact structure. The first and second contact structures and the intrinsic semiconductor layer are formed in alternating sequence such that the first contact structure adjoins a first surface (e.g. a “top” surface) of the intrinsic semiconductor layer and the second contact structure adjoins a second (e.g. “bottom”) surface of the intrinsic semiconductor layer. The first and second contact structures establish a built-in electric field across the intrinsic semiconductor layer.

The method preferably further includes forming more than one wide band gap semiconductor layer and causing at least one of the one or more narrow band gap semiconductor layers to be formed between two wide band gap semiconductor layers during the step of forming the first contact structure. As discussed above, forming the narrow band gap semiconductor layer between wide band gap layers facilitates transfer doping. In accordance with one or more embodiments of the method, the intrinsic semiconductor layer is comprised of hydrogenated amorphous silicon. In one or more embodiments, the intrinsic semiconductor layer further comprises germanium. The step of forming the second contact structure in one or more embodiments of the method further includes forming a wide band gap semiconductor n-layer and a narrow band gap semiconductor layer in adjoining relation to each other such that the narrow band gap semiconductor layer is transfer doped by the wide band gap semiconductor n-layer. The step of forming the first contact structure in one or more embodiments of the method further includes forming each of the narrow band gap semiconductor layers to a thickness between 3-30 nm and each of the wide band gap semiconductor layers to a thickness between 5-25 nm. As discussed above with respect to FIG. 7B, the formation of the above-referenced layers may be effected using PECVD. The step of forming the first contact structure further includes causing the total thickness of the narrow band gap semiconductor layers to be less than 75 nm and the total thickness of the wide band gap semiconductor layers to be less than 50 nm in some embodiments. A metal contact layer is formed on the second contact structure in some embodiments, such as the metal layer 62 shown in FIG. 7B. The method includes obtaining a transparent substrate and forming the first, electrically conductive, multi-layer p-type contact structure on the substrate in one or more embodiments. The step of forming the second, electrically conductive n-type contact structure in some embodiments further includes forming one or more wide band gap n-type semiconductor layers and a narrow band gap semiconductor layer between and adjoining the first and second wide band gap n-type semiconductor layers such that the narrow band gap semiconductor layer in the n-type contact structure is transfer doped by the adjoining band gap n-type semiconductor layers. The intrinsic semiconductor layer 22 comprises a-SiₓGe₁₋ₓ:H where 0≦x≦1 in one or more embodiments of the exemplary method.

A method substantially as described above may alternatively provide a multi-layer contact structure including n+ layer(s) for enhancing the built-in electric field across the i-layer 22. Such a method involves causing transfer doping of the narrow band gap layer(s) 26A by transferring electrons from the wide band gap semiconductor layers 26B into the narrow band gap layers. A p-type contact layer that may or may not be multi-layer is formed on the opposite side of the i-layer. The method may further include forming the multilayer contact structure such that each narrow band gap contact layer of the n-type contact structure adjoins two wide band gap semiconductor layers such as shown in FIG. 3. The method may include forming the contact structure such that one of the wide band gap semiconductor layers 26B adjoins the i-layer and the narrow band gap contact layer. A second of the wide band gap semiconductor layers adjoins the narrow band gap layer. The photosensitive material comprising the i-layer used in the method may comprise a-SiₓGe₁₋ₓ:H where 0≦x≦1. As discussed above, an amorphous i-layer may or may not include microcrystalline and/or nanocrystalline portions.

An exemplary method of fabricating a p-i-n photodetector structure having a multi-layer n-type contact structure includes forming a first, electrically conductive, multi-layer n-type contact structure including one or more wide band gap semiconductor layers and one or more narrow band gap semiconductor layers in alternating sequence such that the one or more narrow band gap semiconductor layers are transfer doped by at least one of the one or more wide band gap semiconductor layers, forming a photosensitive hydrogenated amorphous, nanocrystalline or microcrystalline intrinsic semiconductor layer, and forming a second, electrically conductive p-type contact structure. The first and second contact structures and the intrinsic semiconductor layer are formed in alternating sequence such that the first contact structure adjoins a first surface of the intrinsic semiconductor layer and the second contact structure adjoins a second surface of the intrinsic semiconductor layer, forming a p-i-n photodetector structure. The method in accordance with one or more embodiments further includes forming more than one wide band gap semiconductor layer and causing at least one of the one or more narrow band gap semiconductor layers to be formed between two wide band gap semiconductor layers of the first contact structure. As discussed above, this process enhances transfer doping of the narrow band gap semiconductor layer. One of the wide band gap semiconductor layers may adjoin the intrinsic semiconductor layer as well as the narrow band gap semiconductor layer. The intrinsic semiconductor layer is comprised of a-SiₓGe₁₋ₓ:H where 0≦x≦1 in one or more embodiments of the method. The step of forming the first contact structure further includes forming each of the one or more narrow band gap semiconductor layers to a thickness between 3-30 nm and each of the wide band gap semiconductor layers to a thickness between 5-25 nm in some embodiments of the method. The step of forming the first contact structure further includes causing the total thickness of the one or more narrow band gap semiconductor layers to be less than 75 nm and the total thickness of the wide band gap semiconductor layers to be less than 50 nm in one or more embodiments.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Terms such as “top” and “bottom” are used to designate relative positions of elements as opposed to elevation. For example, the “top” surface of a structure can face up, down, or any other direction.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A p-i-n photodetector structure comprising:
a photosensitive intrinsic amorphous, nanocrystalline or microcrystalline semiconductor layer having top and bottom surfaces;
a first electrically conductive contact structure having a first doping type adjoining the top surface of the intrinsic semiconductor layer, the first contact structure including first and second wide band gap semiconductor layers and a transfer doped narrow band gap contact layer between and adjoining the first and second wide band gap semiconductor layers, and
a second electrically conductive contact structure adjoining the bottom surface of the intrinsic semiconductor layer, the second contact structure comprising a semiconductor material having a second doping type opposite to the first doping type, the first and second contact structures establishing a built-in electric field across the intrinsic semiconductor layer.

2. The photodetector structure of claim 1, further including a metal contact layer on the second contact structure.

3. The photodetector structure of claim 1, wherein the intrinsic semiconductor layer comprises hydrogenated amorphous silicon and the narrow band gap contact layer is comprised of hydrogenated amorphous silicon (a-Si:H), hydrogenated microcrystalline silicon (μc-Si:H), hydrogenated amorphous silicon germanium (a-SiGe:H), hydrogenated microcrystalline silicon germanium (μ-SiGe:H), hydrogenated microcrystalline silicon germanium oxide (μ-SiGeO:H), or hydrogenated microcrystalline silicon carbon (μc-SiC:H).

4. The photodetector structure of claim 3, wherein the first wide band gap semiconductor layer is comprised of a material selected from the group consisting of a-SiC:H, μc-SiC:H, a-SiO:H, μc-SiO:H, a-SiN:H, μc-SiN:H, a-C:H and combinations thereof.

5. The photodetector structure of claim 1, wherein the first contact structure is p-type and the second contact structure is n-type.

6. The photodetector structure of claim 5, wherein the first contact structure includes a plurality of narrow band gap contact layers.

7. The photodetector structure of claim 5, wherein the narrow band gap contact layer has a thickness between 3-30 nm and each of the wide band gap semiconductor layers has a thickness between 5-25 nm.

8. The photodetector structure of claim 7, wherein the total thickness of the wide band gap semiconductor layers is less than 50 nm.

9. The photodetector structure of claim 5, wherein the intrinsic semiconductor layer comprises a-SiₓGe₁₋ₓ:H where 0≦x≦1.

10. The photodetector structure of claim 5, wherein the intrinsic semiconductor layer comprises hydrogenated amorphous silicon.

11. The photodetector structure of claim 1, wherein the second electrically conductive contact structure is an n-type layer comprising first and second wide band gap n-type semiconductor layers and a transfer doped narrow band gap semiconductor layer between and adjoining the first and second wide band gap n-type semiconductor layers.

12. The photodetector structure of claim 1, wherein the first contact structure is n-type.

13. A p-i-n photodetector structure comprising:
a photosensitive intrinsic amorphous, nanocrystalline or microcrystalline semiconductor layer having top and bottom surfaces;
an electrically conductive p-type first contact structure adjoining the top surface of the intrinsic semiconductor layer, the first contract structure comprising one or more wide band gap semiconductor layers and one or more narrow band gap semiconductor layers, the one or more narrow band gap semiconductor layers having band gaps smaller than those of the wide band gap semiconductor layers, the one or more narrow band gap semiconductor layers and the one or more wide band gap semiconductor layers being arranged in alternating sequence, each of the one or more narrow band gap semiconductor layers adjoining at least one wide band gap semiconductor layer and being transfer doped by at least one of the one or more wide band gap semiconductor layers, and
an electrically conductive second contact structure comprised of n-type semiconductor material adjoining the bottom surface of the intrinsic semiconductor layer, the first and second contact structures establishing a built-in electric field across the intrinsic semiconductor layer.

14. The photodetector structure of claim 13, wherein the intrinsic semiconductor layer is comprised of a-SiₓGe₁₋ₓ:H where 0≦x≦1.

15. The photodetector structure of claim 14, wherein the intrinsic semiconductor layer has a microcrystalline portion.

16. The photodetector structure of claim 14, wherein the intrinsic amorphous semiconductor layer further comprises germanium.

17. The photodetector structure of claim 14, wherein at least one of the one or more narrow band gap semiconductor layers is comprised of hydrogenated amorphous silicon (a-Si:H), hydrogenated microcrystalline silicon (μc-Si:H), hydrogenated amorphous silicon germanium (a-SiGe:H), hydrogenated microcrystalline silicon germanium (μ-SiGe:H), hydrogenated microcrystalline silicon germanium oxide (μ-SiGeO:H), or hydrogenated microcrystalline silicon carbon (μc-SiC:H).

18. The photodetector structure of claim 14, wherein each of the one or more narrow band gap semiconductor layers has a thickness between 3-30 nm and each of the one or more wide band gap semiconductor layers has a thickness between 5-25 nm.

19. The photodetector structure of claim 14, further including more than one wide band gap semiconductor layer, wherein at least one of the one or more narrow band gap semiconductor layers adjoins two wide band gap semiconductor layers.

20. The photoreceptor of claim 19, wherein one or more of the wide band gap semiconductor layers are comprised of a-SiC:H, a-SiO:H, a-SiN:H, or a combination thereof.

21. A p-i-n photodetector structure comprising:
a photosensitive intrinsic amorphous, nanocrystalline or microcrystalline semiconductor layer having top and bottom surfaces;
an electrically conductive n-type first contact structure adjoining the top surface of the intrinsic semiconductor layer, the first contract structure comprising one or more wide band gap semiconductor layers and one or more narrow band gap semiconductor layers, the one or more narrow band gap semiconductor layers having band gaps smaller than those of the wide band gap semiconductor layers, the one or more narrow band gap semiconductor layers and the one or more wide band gap semiconductor layers being arranged in alternating sequence, each of the one or more narrow band gap semiconductor layers adjoining at least one wide band gap semiconductor layer and being transfer doped by at least one of the one or more wide band gap semiconductor layers, and
an electrically conductive second contact structure comprised of p-type semiconductor material adjoining the bottom surface of the intrinsic semiconductor layer, the first and second contact structures establishing a built-in electric field across the intrinsic semiconductor layer.

22. The photodetector structure of claim 21, wherein the intrinsic semiconductor layer comprises a-SiₓGe₁₋ₓ:H where 0≦x≦1.

23. The photodetector structure of claim 22, wherein each of the one or more narrow band gap semiconductor layers has a thickness between 3-30 nm and each of the one or more wide band gap semiconductor layers has a thickness between 5-25 nm.

24. The photodetector structure of claim 22, further including more than one wide band gap semiconductor layer, wherein at least one of the one or more narrow band gap semiconductor layers adjoins two wide band gap semiconductor layers.

25. The photodetector structure of claim 24, wherein the total thickness of the wide band gap semiconductor layers is less than 50 nm.
